(19) United States
(12) Patent Application Publication
(10) Pub. No.: US 2026/0206178 A1
(43) Pub. Date: Jul. 16, 2026

(54) Liquid Flow Channel Flat Tube Structure

(71) Applicant: Xiao Zeng, Zhuhai City (CN)

(72) Inventors: Xiao Zeng, Zhuhai City (CN); Yun Zeng, Zhuhai City (CN); JianFen Zhang, Zhuhai City (CN)

(21) Appl. No.: 19/019,972

(22) Filed: Jan. 14, 2025

(51) Int. Cl. H05K 7/20

(52) U.S. Cl. CPC H05K 7/20263; H05K 7/20272; H05K 7/20763

(57) ABSTRACT

A liquid flow channel flat tube structure, comprising a special-shaped copper tube and a solid copper plate, wherein the special-shaped copper tube is a flat tube, and it is formed by bending and flattening a copper tube; the solid copper plate is welded to the special-shaped copper tube to form an integrated heat dissipation module, thereby achieving overall heat dissipation. The invention belongs to the technical field of heat dissipation, and specifically refers to a liquid flow channel flat tube structure.

### TECHNICAL FIELD

The invention belongs to the technical field of heat dissipation, and specifically refers to a liquid flow channel flat tube structure.

### BACKGROUND ART

As the computing power of database servers continues to upgrade, the power of its internal components such as the CPU, GPU, memory stick and storage module continues to increase, and the heat generated also increases significantly. At the same time, the design trend of servers is moving towards a more compact direction, which makes the space where the cooling module can be installed extremely strictly limited.

In this case, traditional heat dissipation hardware configuration faces many severe challenges. On the one hand, it is difficult to achieve high-performance heat dissipation in a narrow installation space, resulting in poor heat dissipation of local chips under high computing power and high power conditions, which is prone to overheating and not only affects the performance stability of the server, but also may shorten its service life;

on the other hand, the existing heat dissipation hardware configuration cannot fully adapt to the high-pressure and high-temperature operating conditions of the unit, and physical characteristics such as deformation, tube expansion, and extrusion may occur, posing a destructive threat to the chip and failing to guarantee the reliability and stability of the server under high-load operation. Therefore, there is an urgent need for a heat dissipation flat tube structure that can achieve efficient heat dissipation in a limited space and has high strength and good stability to meet the heat dissipation needs of current database servers.

### SUMMARY OF THE INVENTION

In view of the above situation, in order to overcome the defects of the prior art, the invention provides a liquid flow channel flat tube structure, which effectively solves the problems of poor heat dissipation and insufficient strength and stability in a limited space.

In order to achieve the above function, the invention adopts the following technical solution: a liquid flow channel flat tube structure, comprising a special-shaped copper tube and a solid copper plate, wherein the special-shaped copper tube is a flat tube, and it is formed by bending and flattening a copper tube; the solid copper plate is welded to the special-shaped copper tube to form an integrated heat dissipation module, thereby achieving overall heat dissipation.

Preferably, the solid copper plate is installed above the special-shaped copper tube or installed above and below it simultaneously; the solid copper plate located above the special-shaped copper tube is embedded in the special-shaped copper tube.

Preferably, the special-shaped copper tube has different combination forms, and its length, width, and thickness can be designed and applied according to actual use.

Preferably, the special-shaped copper tube and the solid copper plate are combined by brazing or fixed soldering.

Preferably, the solid copper plate is provided with an avoidance feature.

After adopting the above structure, the invention achieves the following beneficial effects:

1. while maintaining the original narrow installation space, the liquid flow channel flat tube structure according to the invention can effectively meet the dual performance requirements of assembly and heat dissipation, ensuring efficient circulation of coolant in the flat tube and achieving rapid cooling of heating components. Heat dissipation solves the problem of poor heat dissipation of local chips and significantly improves the heat dissipation efficiency of the entire server, thereby ensuring that high-power hardware operates in a stable temperature environment and improving the performance and reliability of the server.

2. The invention can be adaptively designed according to different heat dissipation structures. According to the heat dissipation requirements of various components inside the server, the structure of the flat tube and the coolant flow channel can be flexibly adjusted, so that the heat dissipation capacity can accurately match different heat sources, always maintain a good heat dissipation effect, and adapt to various server hardware configurations and heat dissipation scenarios.

3. The invention adopts the process of bending a copper tube as well as clamping it flat and then brazing it with a solid copper plate, which greatly enhances the overall strength of the flat tube. Compared with the traditional hollow structure flat tube, it effectively solves the problems of tube expansion, deformation and extrusion, ensuring that the flat tube structure can remain stable under high pressure and high temperature environment, and will not cause damage to components such as chips due to physical deformation, providing reliable protection for high-power parts and improving the operating safety and stability of the server.

4. The manufacturing process of the invention is relatively simple and can be achieved by optimizing the existing conventional parts processing technology and welding technology, which not only reduces the production difficulty and cost, but also improves production efficiency and product quality. Through the optimized processing technology, the welding quality level of the entire group of products can be improved, and the defective rate in the production process can be reduced. It provides strong technical support for large-scale mass production, and also enhances the reliability, rationality and economy of the processing technology.

5. The flat tube has the characteristic of free combination, and its length, width, thickness, and combination form can be customized and adjusted according to the actual application scenario, which enables the flat tube structure to flexibly adapt to the internal space layout and heat dissipation requirements of different servers, solving the assembly problems caused by small space and complex structure, such as installation difficulties and thickness interference, and providing greater freedom and convenience for server design and manufacturing.

### BRIEF DESCRIPTION OF THE DRAWINGS

FIG. 1 is a first schematic diagram of an overall structure of the liquid flow channel flat tube structure according to the invention;

FIG. 2 is a second schematic diagram of an overall structure of the liquid flow channel flat tube structure according to the invention;

FIG. 3 is a third first schematic diagram of an overall structure of the liquid flow channel flat tube structure according to the invention;

FIG. 4 is a fourth schematic diagram of an overall structure of the liquid flow channel flat tube structure according to the invention;

FIG. 5 is a first exploded view of the liquid flow channel flat tube structure according to the invention;

FIG. 6 is a second exploded view of the liquid flow channel flat tube structure according to the invention;

FIG. 7 is a first diagram showing the liquid flow channel flat tube structure in use according to the invention;

FIG. 8 is a second diagram showing the liquid flow channel flat tube structure in use according to the invention;

FIG. 9 is a third diagram showing the liquid flow channel flat tube structure in use according to the invention;

FIG. 10 is a fourth diagram showing the liquid flow channel flat tube structure in use according to the invention;

In the figures: 1 refers to the special-shaped copper tube; 2 refers to the solid copper plate; 3 refers to the avoidance feature.

### SPECIFIC EMBODIMENT OF THE INVENTION

The technical solutions in the embodiments of the invention will be clearly and completely described hereinafter with reference to the drawings in the embodiments of the invention. Obviously, the described embodiments are only a part of the embodiments of the invention, rather than all the embodiments. Based on the embodiments of the invention, all other embodiments obtained by those of ordinary skill in the art without creative efforts shall fall within the protection scope of the invention.

In the description of the invention, it needs to be understood that the orientation or positional relationship indicated by the terms “center”, “up”, “down”, “left”, “right”, “vertical”, “horizontal”, “inner”, “outer”, etc. are based on the orientation or positional relationship shown in the drawings, which are only for the convenience of describing the invention and simplifying the description, rather than indicating or implying that the device or element referred to must have a specific orientation, be constructed and operated in a specific orientation, and therefore cannot be understood as a limitation of the invention. In addition, the terms “first”, “second”, and “third” are only used for descriptive purposes, and cannot be understood as indicating or implying relative importance or implicitly indicating the number of indicated technical features.

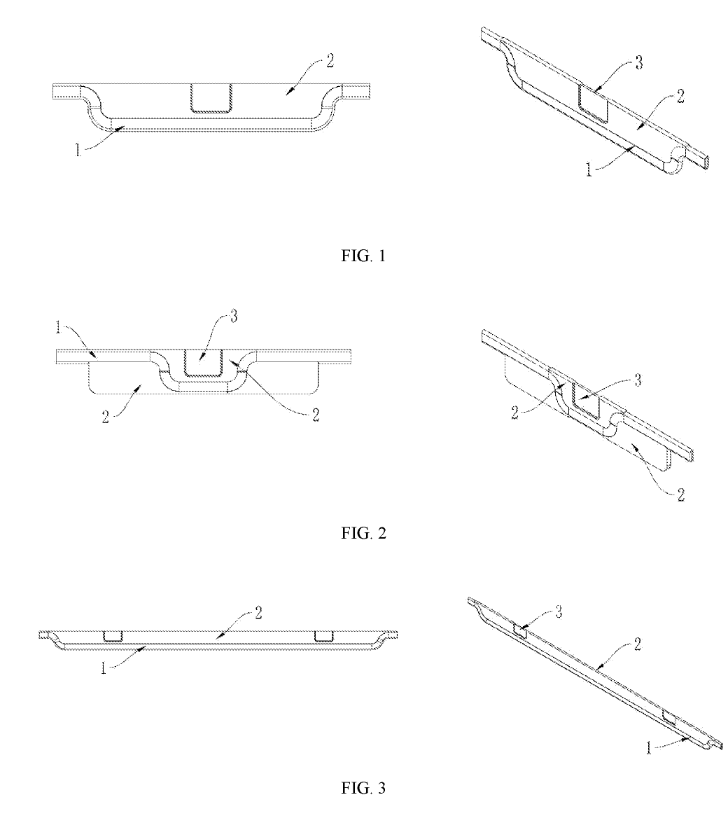

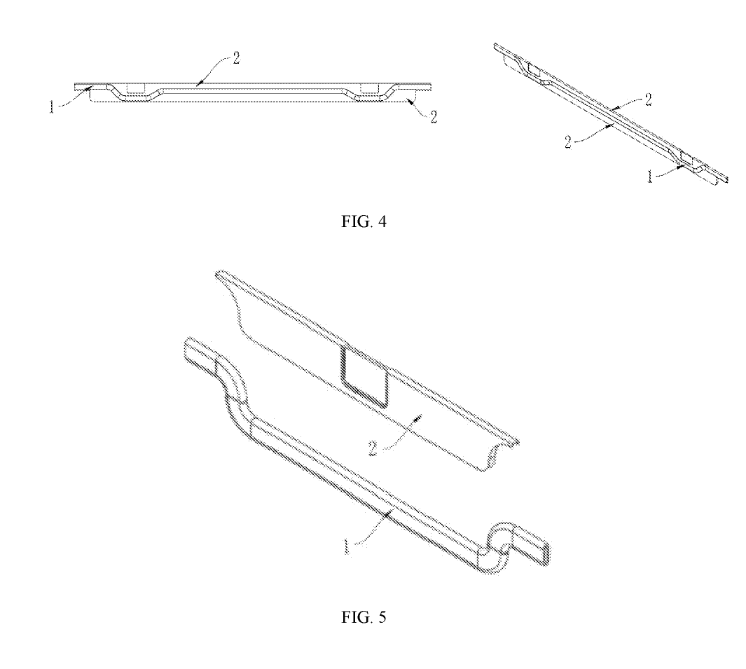

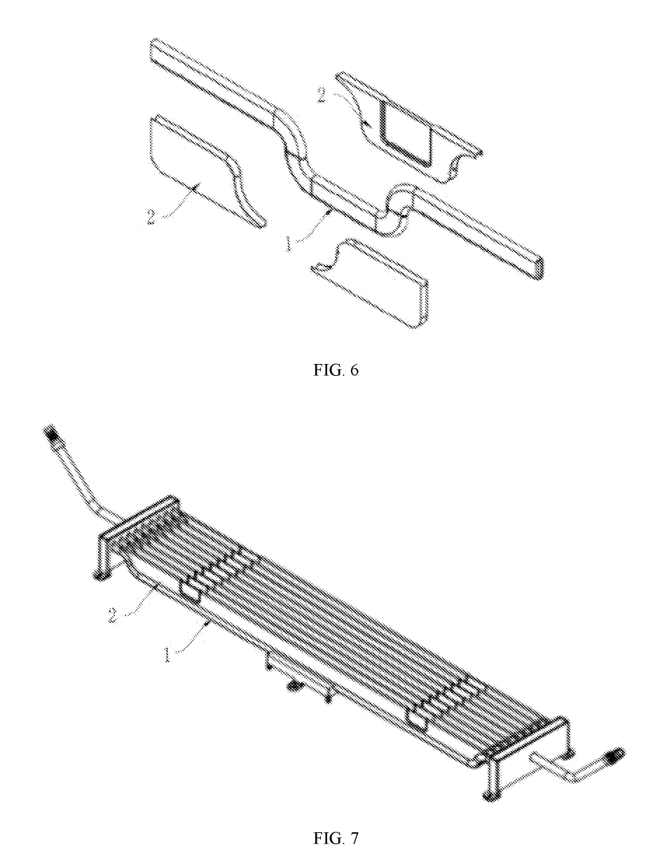

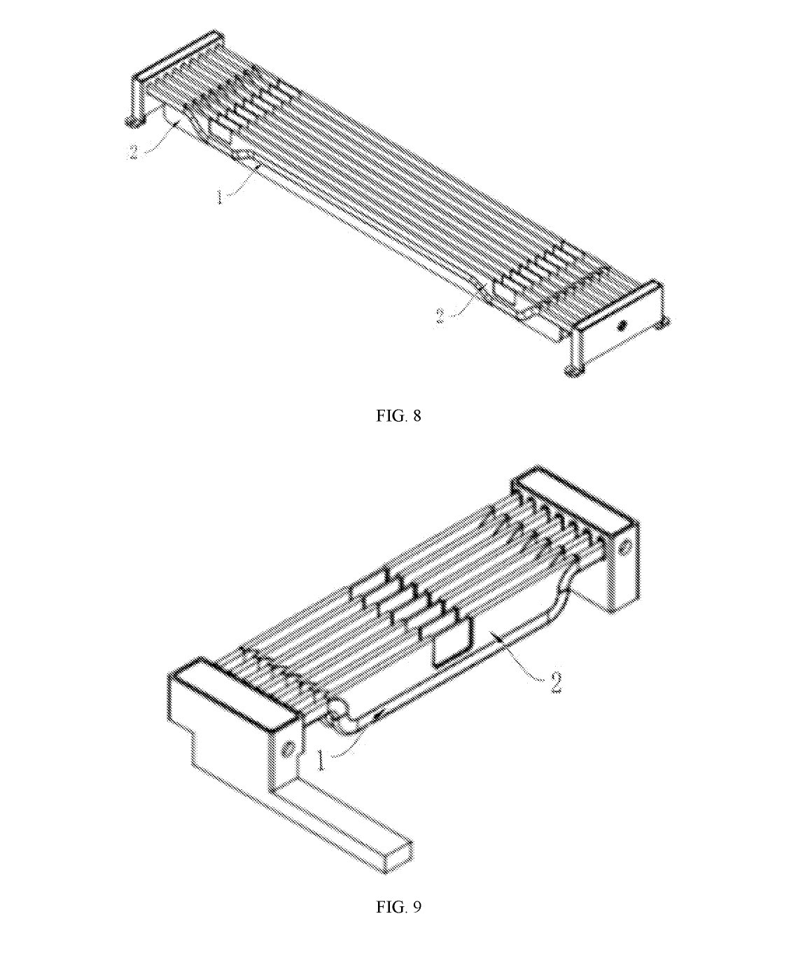

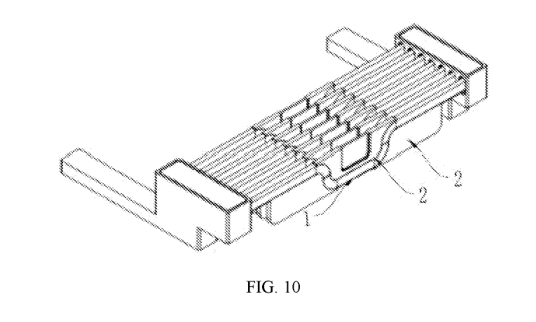

As shown in FIGS. 1-10, the invention provides a liquid flow channel flat tube structure, comprising a special-shaped copper tube 1 and a solid copper plate 2, wherein the special-shaped copper tube 1 is a flat tube, and it is formed by bending and flattening a copper tube; the solid copper plate 2 is welded to the special-shaped copper tube 1 to form an integrated heat dissipation module, thereby achieving overall heat dissipation; the special-shaped copper tube 1 and the solid copper plate 2 are combined by brazing or fixed soldering, and then reassembled with the shunt parts of the heat dissipation module to form a flow channel; the solid copper plate 2 is provided with an avoidance feature 3 to facilitate assembly and avoid interference.

The solid copper plate 2 is installed above the special-shaped copper tube 1 or installed above and below it simultaneously; the solid copper plate 2 located above the special-shaped copper tube 1 is embedded in the special-shaped copper tube 1; the solid copper plate 2 can absorb and store more heat, thereby enhancing the heat dissipation efficiency; at the same time, it can be used as a reinforcement structure to form a more stable whole, so that the heat dissipation module can better withstand various stresses during transportation, installation and use.

The special-shaped copper tube 1 has different combination forms, and its length, width, and thickness can be designed and applied according to actual use.

In specific embodiment, copper tubes of appropriate specifications and purity are selected as basic materials to ensure that they have good thermal conductivity and machinability. The copper tubes are used to construct fluid channels. At the same time, a sufficient number of solid copper plates 2 are prepared to enhance the structural strength and heat dissipation performance of the flat tubes, as well as other auxiliary materials such as brazing solder, fixing tin solder, etc.

First, the copper tube is subjected to a profiling bending process to make its shape compatible with the installation space and heat dissipation layout inside the server. According to the predetermined installation width, the bent copper tube is clamped and flattened to form a flat tube shape, which serves as the bottom lining part of the overall flat tube solution.

The solid copper plate 2 and the special-shaped copper tube 1 are precisely matched to ensure that the contact surfaces of the two are flat and tightly fitted, and then they are firmly welded together by brazing to form a stable integrated heat dissipation module. For some parts that need further reinforcement or special connection, auxiliary welding methods such as fixed soldering can be used to ensure the integrity and stability of the entire flat tube structure.

After the processing and assembly of the flat tube unit is completed, it is reassembled with the diverter parts of the heat dissipation module. According to the heat dissipation requirements and coolant circulation design of the server, the flat tube and the diverter are precisely connected to ensure that the coolant can circulate smoothly and efficiently in the flow channel system composed of the flat tube and the diverter to form a complete heat dissipation circuit, thereby achieving effective heat dissipation of various heat-generating components inside the server.

In actual applications, the flat tube structure is adaptively designed and optimized according to the hardware configuration and heat dissipation requirements of different servers. By analyzing the characteristics of the heat dissipation area of the components that need to be de-heated, such as area size, heat distribution, etc., different flat tube combinations, lengths, widths and thicknesses, as well as the layout and direction of the coolant flow channel are flexibly set to achieve the most optimized overall heat dissipation solution, maximize the heat dissipation performance, and meet the heat dissipation requirements of the server under various working conditions.

At the same time, according to the changes in the internal space of the server and the adjustment of the structure, free combination characteristics of the flat tube monomers is fully utilized to carry out customized structural design and assembly, ensuring that the flat tube structure can perfectly adapt to different application scenarios, effectively solving various problems that may arise during the installation process, and improving the overall performance and reliability of the server.

The invention and the embodiments thereof are described hereinabove, and this description is not restrictive. What is shown in the drawings is only one of the embodiments of the invention, and the actual structure is not limited thereto. All in all, structural methods and embodiments similar to the technical solution without deviating from the purpose of the invention made by those of ordinary skill in the art without creative design shall all fall within the protection scope of the invention.

1. A liquid flow channel flat tube structure, comprising a special-shaped copper tube and a solid copper plate, wherein the special-shaped copper tube is a flat tube, and it is formed by bending and flattening a copper tube; the solid copper plate is welded to the special-shaped copper tube to form an integrated heat dissipation module, thereby achieving overall heat dissipation.

2. The liquid flow channel flat tube structure of claim 1, wherein the solid copper plate is installed above the special-shaped copper tube or installed above and below it simultaneously; the solid copper plate located above the special-shaped copper tube is embedded in the special-shaped copper tube.

3. The liquid flow channel flat tube structure of claim 2, wherein the special-shaped copper tube has different combination forms, and its length, width, and thickness can be designed and applied according to actual use.

4. The liquid flow channel flat tube structure of claim 3, wherein the special-shaped copper tube and the solid copper plate are combined by brazing or fixed soldering.

5. The liquid flow channel flat tube structure of claim 4, wherein the solid copper plate is provided with an avoidance feature.
